(19) United States
(12) Patent Application Publication
(10) Pub. No.: US 2013/0220211 A1
(43) Pub. Date: Aug. 29, 2013

(54) CRYSTAL TO CRYSTAL OXYGEN EXTRACTION

(71) Applicants: Indrajit Dutta, Horseheads, NY (US); Shawn Michael O'Malley, Horseheads, NY (US); Vitor Marino Schneider, Painted Post, NY (US)

(72) Inventors: Indrajit Dutta, Horseheads, NY (US); Shawn Michael O'Malley, Horseheads, NY (US); Vitor Marino Schneider, Painted Post, NY (US)

(21) Appl. No.: 13/765,800

(22) Filed: Feb. 13, 2013

Related U.S. Application Data
(60) Provisional application No. 61/604,729, filed on Feb. 29, 2012.

(51) Int. Cl. C30B 1/04

(52) U.S. Cl. CPC C30B 1/04
USPC 117/7

(57) ABSTRACT

Compositions made by metallothermal reduction from crystalline materials and methods of producing such compositions are provided. The compositions have novel crystalline structures in the form of three-dimensional scaffolds. Additionally, the compositions possess unusual properties that indicate possible applications in numerous applications.

### CROSS-REFERENCE TO RELATED APPLICATIONS

This application claims the benefit of priority under 35 U.S.C. §119 of U.S. Provisional Application Ser. No. 61/604,729 filed on Feb. 29, 2012, the content of which is relied upon and incorporated herein by reference in its entirety.

### FIELD

Embodiments generally relate to crystalline compositions formed by metallothermal reduction and methods of producing such compositions. More particularly, embodiments relate to single- or multi-element crystalline compositions formed by metallothermal processes that have unique structures, and methods of producing such compositions.

### BACKGROUND

There is a growing interest in controlling the shape and properties of materials at sizes on the nano- and microscale. Materials with features on this scale have potential uses in a large number of areas, such as in electronics, fuel cells, pH- and other types of sensors, catalysts, and biotechnology. However, the continuing challenge in developing such materials is how to efficiently and effectively produce them.

Crystalline structures have many advantages in that they provide a highly ordered and reproducible structure. However, one limitation with the formation of some crystalline compounds has been that highly pure elements in their zero valence state are difficult to obtain, and up until now, large quantities of pure, highly ordered/crystalline elements in their zero valence state in commercial-scale quantities were nearly impossible to obtain.

### SUMMARY

Embodiments described herein are directed to forming novel products utilizing metallothermic processes on three-dimensional crystalline structures comprising both single and multiple elements, and methods of forming such products.

A first aspect comprises metallothermic processes to convert an oxygen-containing crystalline composition into an oxygen-free atomic or molecular composition. In some embodiments, the resulting oxygen-free composition will comprise a similar or identical crystalline structure. In some embodiments, the resulting oxygen-free composition will comprise a different or new crystalline structure. Using the metallothermic process (e.g., magnesiothermic processes) provides a very effective means of converting the oxygen-containing crystal lattice into its respective oxygen-free form. The crystal structure may be either single or polycrystalline in form. Additionally, the crystal structure may contain porous or three-dimensional mesoporous scaffold geometry.

Another aspect comprises oxygen-free compositions with new properties not observed in the starting lattice or in similar compositions formed using different processes. In one embodiment, the crystal-to-crystal conversion process provides a method for conversion of large-scale, single crystal silicon from quartz. Embodiments are especially useful for preparing substrates for the photovoltaics, microelectronics and semiconductor industries as many methods exist to make quartz and quartz films including sol gel processes.

One embodiment comprises a composition comprising an essentially oxygen-free crystalline composition wherein the composition is formed by metallothermic reduction of an oxygen-containing crystalline precursor and the composition comprises a lattice arrangement derived from the oxygen-containing crystalline precursor. In some embodiments, the oxygen-containing crystalline precursor of the oxygen-free crystalline composition comprises two or more elements other than oxygen. In some embodiments, the essentially oxygen-free crystalline composition comprises a periodic arrangement of holes. In some embodiments, the essentially oxygen-free crystalline composition comprises a porosity of greater than 200 m²/gram. In some embodiments, the oxygen-containing crystalline precursor comprises zeolite, mica, quartz, sapphire, oxyorthosilicate, perovskites, a nonlinear optical crystal, metal oxide organic framework, a metal organic framework, an atomic layer deposition (ALD) crystal, a sol gel crystal, quartz fibers, crystal fibers.

Another embodiment comprises an essentially oxygen-free crystalline composition formed by metallothermic reduction of an oxygen-containing crystalline precursor, wherein the composition comprises a different lattice arrangement than the oxide precursor. In some embodiments, the essentially oxygen-free crystalline composition comprises a periodic arrangement of holes. In some embodiments, the essentially oxygen-free crystalline composition comprises a porosity of greater than 200 m²/gram. In some embodiments, the oxygen-containing crystalline precursor comprises zeolite, mica, quartz, sapphire, oxyorthosilicate, perovskites, a nonlinear optical crystal, metal oxide organic framework, a metal organic framework, an ALD crystal, a sol gel crystal, quartz fibers, crystal fibers.

Another embodiment comprises a composition comprising a zeolite or quartz lattice structure, wherein the composition comprises silicon and is essentially free of oxygen.

Another embodiment comprises a method of forming an essentially oxygen-free crystalline composition comprising subjecting an oxygen-containing crystalline precursor to a metallothermic process and removing reaction by-products to give an essentially oxygen-free crystalline composition. In some embodiments, the essentially oxygen-free crystalline composition comprises the same lattice arrangement as the oxygen-containing crystalline precursor. In some embodiments, the essentially oxygen-free crystalline composition comprises a different lattice arrangement than the oxygen-containing crystalline precursor. In some embodiments, the oxygen-containing crystalline precursor of the oxygen-free crystalline composition comprises two or more elements other than oxygen. In some embodiments, the oxygen-free crystalline composition comprises a periodic arrangement of holes. In other embodiments, the oxygen-free crystalline composition comprises a porosity of greater than 200 m²/gram.

In some embodiments, the method of forming an essentially oxygen-free crystalline composition comprises subjecting an oxygen-containing crystalline precursor to a metallothermic process and removing reaction by-products to give an essentially oxygen-free crystalline composition, further comprises subjecting the oxygen-containing crystalline composition to a metallothermic process comprises heating to a temperature of greater than 400° C. for more than 2 hours. In some embodiments, the subjecting the oxygen-containing crystalline composition to a metallothermic process comprises heating to a temperature of greater than 400° C. for more than 2 hours and subsequently, heating to a temperature of greater than 600° C. for more than 2 hours. In some embodiments, removing reaction by-products comprises acid etching the essentially oxygen-free crystalline composition.

In some embodiments, the method of forming an essentially oxygen-free crystalline composition comprising subjecting an oxygen-containing crystalline precursor to a metallothermic process and removing reaction by-products to give an essentially oxygen-free crystalline composition, further comprises placing the oxygen-containing crystalline precursor on a holding matrix. In other embodiments, the method further comprises modifying the oxygen-containing crystalline precursor. In some embodiments, modifying the oxygen-containing crystalline precursor comprises doping, chemically modifying, or physically modifying the oxygen-containing crystalline composition. In other embodiments, the method further comprises modifying the essentially oxygen-free crystalline composition. In some embodiments, modifying the essentially oxygen-free crystalline composition comprises doping, chemically modifying, or physically modifying the essentially oxygen-free crystalline composition. In some embodiments, the method further comprises masking or patterning the oxygen-containing crystalline precursor. In some embodiments, the method further comprises masking or patterning the essentially oxygen-free crystalline composition. In some embodiments, the composition used for masking or patterning comprises carbon. In some embodiments, the method further comprises use of the essentially oxygen-free crystalline composition for growing crystals. In some embodiments, growing crystals comprises epitaxy.

Another embodiments comprises a method comprising subjecting an oxygen-containing crystalline precursor to a metallothermic process and removing reaction by-products to give an essentially oxygen-free crystalline composition, wherein the porosity of a crystalline composition is greater than the porosity of the precursor. In some embodiments, the essentially oxygen-free crystalline composition comprises a periodic arrangement of holes. In some embodiments, the essentially oxygen-free crystalline composition comprises a porosity of greater than 200 m²/gram. In some embodiments, the oxygen-containing crystalline precursor comprises zeolite, mica, quartz, sapphire, oxyorthosilicate, perovskites, a nonlinear optical crystal, metal oxide organic framework, a metal organic framework, an atomic layer deposition (ALD) crystal, a sol gel crystal, quartz fibers, crystal fibers. In other embodiments, the method further comprises modifying the oxygen-containing crystalline precursor. In some embodiments, modifying the oxygen-containing crystalline precursor comprises doping, chemically modifying, or physically modifying the oxygen-containing crystalline composition. In other embodiments, the method further comprises modifying the essentially oxygen-free crystalline composition. In some embodiments, modifying the essentially oxygen-free crystalline composition comprises doping, chemically modifying, or physically modifying the essentially oxygen-free crystalline composition.

### BRIEF DESCRIPTION OF THE DRAWINGS

FIG. 1—Low magnification bifocal transmission electron microscope (“TEM”) images of starting alumina-silica based zeolite cube (FIG. 1A) and silicon cube obtained after oxygen extraction (FIG. 1B). The oxygen extracted sample was taken from essentially pure silicon sample (see XRD from Table 5). Samples are approximately 3×3×4 μm.

FIG. 2—FIG. 2A shows a low magnification image of the methallothermal reduced and etched Zeolite 3A, showing the interconnected structure; FIG. 2B is a picture of the same material showing a lamellar structure; FIGS. 2C and 2D show the lattice fringes which are similar to cubic silicon structure with d-spacing of 5.49 Å. Note the presence of amorphous layer highlighted in FIG. 2D around 3-5 nm thick at the edge of the crystalline particles. It was found that the amorphous layer primarily consisted of aluminum and oxygen.

FIG. 3—High angle annular dark field (“HAADF”) image of a flakey silicon region (FIG. 3A), with FIGS. 3B-3D showing silicon, Al and O maps, respectively. The amorphous phase is mostly Al and O. Note also that FIG. 3B, the signature for silicon, matches best with the FIG. 3D, the pattern for oxygen, while FIG. 3C, shows aluminum only on the edges of the structure. This would seem to indicate that the amorphous spinel structure is leaching out of the cage lattices near the sides of the cube and that some of the silicon lattice is becoming oxidized. Hence, further extractions might make even more spinel removal.

FIG. 4—FIG. 4A shows a low magnification image of methallothermal reduced Zeolite 3A subjected to 1M HCl acid etching; FIGS. 4B and 4C are high resolution TEM images of different regions showing the silicon lattice fringes. The images show almost no presence of the amorphous phase.

FIG. 5—FIG. 5A is a low magnification image of an amorphous region; FIG. 5B shows a cluster region; FIG. 5C is a selected area electron diffraction (“SAED”) of a cluster region; FIG. 5D shows a high resolution TEM of a flat, sheet-like region showing a graphite-like layered structure.

FIG. 6—High resolution TEM of a crystalline region showing cubic lattice fringes as seen in crystalline silicon.

FIG. 7—FIG. 7A is a zero loss image of a flat region of exfoliated particles, while FIG. 7B is an image of the silicon map and FIG. 7C shows the carbon map.

### DETAILED DESCRIPTION

The present disclosure can be understood more readily by reference to the following detailed description, drawings, examples, and claims, and their previous and following description. However, before the present compositions, articles, devices, and methods are disclosed and described, it is to be understood that this disclosure is not limited to the specific compositions, articles, devices, and methods disclosed unless otherwise specified, as such can, of course, vary. It is also to be understood that the terminology used herein is for the purpose of describing particular aspects only and is not intended to be limiting.

The following description is provided as an enabling teaching. To this end, those skilled in the relevant art will recognize and appreciate that many changes can be made to the various aspects described herein, while still obtaining the beneficial results. It will also be apparent that some of the desired benefits of the present disclosure can be obtained by selecting some of the features without utilizing other features. Accordingly, those who work in the art will recognize that many modifications and adaptations are possible and can even be desirable in certain circumstances and are a part of the present disclosure. Thus, the following description is provided as illustrative of embodiments and not in limitation thereof.

Disclosed are materials, compounds, compositions, and components that can be used for, can be used in conjunction with, can be used in preparation for, or are embodiments of the disclosed methods and compositions. These and other materials are disclosed herein, and it is understood that when combinations, subsets, interactions, groups, etc. of these materials are disclosed that while specific reference of each various individual and collective combinations and permutation of these compounds may not be explicitly disclosed, each is specifically contemplated and described herein. Thus, if a class of substituents A, B, and C are disclosed as well as a class of substituents D, E, and F, and an example of a combination embodiment, A-D is disclosed, then each is individually and collectively contemplated. Thus, in this example, each of the combinations A-E, A-F, B-D, B-E, B-F, C-D, C-E, and C-F are specifically contemplated and should be considered disclosed from disclosure of A, B, and C; D, E, and F; and the example combination A-D. Likewise, any subset or combination of these is also specifically contemplated and disclosed. Thus, for example, the sub-group of A-E, B-F, and C-E are specifically contemplated and should be considered disclosed from disclosure of A, B, and C; D, E, and F; and the example combination A-D. This concept applies to all aspects of this disclosure including, but not limited to any components of the compositions and steps in methods of making and using the disclosed compositions. Thus, if there are a variety of additional steps that can be performed it is understood that each of these additional steps can be performed with any specific embodiment or combination of embodiments of the disclosed methods, and that each such combination is specifically contemplated and should be considered disclosed.

In this specification and in the claims which follow, reference will be made to a number of terms which shall be defined to have the following meanings^{.}

“Include,” “includes,” or like terms means encompassing but not limited to, that is, inclusive and not exclusive.

The term “about” references all terms in the range unless otherwise stated. For example, about 1, 2, or 3 is equivalent to about 1, about 2, or about 3, and further comprises from about 1-3, from about 1-2, and from about 2-3. Specific and preferred values disclosed for compositions, components, ingredients, additives, and like aspects, and ranges thereof, are for illustration only; they do not exclude other defined values or other values within defined ranges. The compositions and methods of the disclosure include those having any value or any combination of the values, specific values, more specific values, and preferred values described herein.

The indefinite article “a” or “an” and its corresponding definite article “the” as used herein means at least one, or one or more, unless specified otherwise.

“Crystal” or “crystalline,” as used herein, refers to a solid material whose constituent atoms, molecules, or ions are arranged in an orderly, repeating pattern extending in all three spatial dimensions. As used herein, crystal or crystalline also include polycrystalline materials, quasicrystals, and crystalline materials that comprise defects, impurities, and/or twinning.

Zeolites are a class of crystalline molecular sieves which are highly porous and are often used for absorption and chemical catalysis. They exist naturally but can be made synthetically via hydrothermal sol-gel synthesis or high pressure hydrothermal synthesis in an autoclave. Metallothermically reduced zeolites into their respective oxygen-free cage-like structure are described below. Zeolites are typically a porous alumina and silica based cage-like materials having sodium or potassium base elements. Zeolites have a porous structure that can accommodate a wide variety of cations, such as Na⁺, K⁺, Ca²⁺, Mg²⁺ and others. Some processes of synthesis include sol gel evaporation, hydrothermal synthesis, autoclave synthesis and crystallization. The most common composition comprises an alumina-silicate, although compositions have been co-doped with metallic catalysts like platinum, palladium, silver and titanium. Zeolites are widely used in all industries for processes such as: catalysis, gas separation, gas and small molecule extraction, sensing, heavy metal clean up surfactants, ion exchange, drug delivery, surfactants, agriculture, petrochemical, and so on.

Examples of zeolites include forms such as sodium Y (334448-100G) and 4A and 5A (Supelco 2-0301) forms, as well as zeolite (Sigma-Aldrich 382280-25G). Further, it is possible to incorporate other metals and metal ions into the pores of the zeolite to yield metal-doped zeolites, which then become oxygen free co-crystals of the metal within the oxygen-free crystal formed from the zeolite.

“Lattice arrangement,” as used herein, refers to a Bravais lattice wherein the crystal is made up of a periodic arrangement of one or more atoms repeated at each lattice point. Consequently, the crystal looks the same when viewed from any of the lattice points.

“Silicon wafer,” as used herein, describes a thin slice of highly pure, single crystalline silicon material.

“Nonlinear crystalline material,” as used herein, describes a crystalline material wherein the dielectric polarization responds nonlinearly to the electric field of the light. Examples of nonlinear crystalline materials include, but are not limited to, barium borate (BBO), lithium iodate, potassium niobate, monopotassium phosphate, lithium triborate, gallium selenide, potassium titanyl phosphate, and ammonium dihydro gen phosphate.

“Essentially oxygen free,” as used herein, refers to a composition that has less than 10 weight percent oxygen. In some embodiments, essentially oxygen free refers to a composition that has 0 to about 10, 0 to about 8, 0 to about 5, 0 to about 4, 0 to about 3, 0 to about 2, 0 to about 1, 0 to about 0.5, 0 to about 1.1, about 0.1 to about 10, about 0.1 to about 9, about 0.1 to about 8, about 0.1 to about 7, about 0.1 to about 6, about 0.1 to about 5, about 0.1 to about 4, about 0.1 to about 3, about 0.1 to about 2, about 0.1 to about 1, about 0.1 to about 0.5, about 0.5 to about 10, about 0.5 to about 9, about 0.5 to about 8, about 0.5 to about 7, about 0.5 to about 6, about 0.5 to about 5, about 0.5 to about 4, about 0.5 to about 3, about 0.5 to about 2, about 0.5 to about 1, about 1 to about 10, about 1 to about 9, about 1 to about 8, about 1 to about 7, about 1 to about 6, about 1 to about 5, about 1 to about 4, about 1 to about 3, about 1 to about 2, about 2 to about 10, about 2 to about 9, about 2 to about 8, about 2 to about 7, about 2 to about 6, about 2 to about 5, about 2 to about 4, about 2 to about 3, about 2 to about 10, about 3 to about 10, about 3 to about 10, about 3 to about 9, about 3 to about 8, about 3 to about 7, about 3 to about 6, about 3 to about 5, about 3 to about 4, about 4 to about 10, about 4 to about 10, about 4 to about 9, about 4 to about 8, about 4 to about 7, about 4 to about 6, about 4 to about 5, about 5 to about 10, about 5 to about 9, about 5 to about 8, about 5 to about 7, about 5 to about 6, about 6 to about 10, about 6 to about 9, about 6 to about 8, about 6 to about 7, about 7 to about 10, about 7 to about 9, about 7 to about 8, about 8 to about 10, about 8 to about 9, or about 9 to about 10 weight percent oxygen. In some embodiments, essentially oxygen free refers to a composition that has less than 10, 9, 8, 7,6, 5, 4, 3, 2, 1, 0.5, 0.1 weight percent oxygen.

“Porosity,” as used herein, is a measure of the void space in the crystalline structure. Porosity may be measured using techniques such as the Barrett, Joyner and Halenda method (BJH) and the Brunauer, Emmer and Teller method (BET), which are standard methods to determine the surface area, pore size and pore size distribution in materials.

“Hole,” as used herein, describes the absence of an atom in a crystalline structure at a location previously occupied due to the crystal undergoing a metallothermic process.

“Holding matrix,” as used herein, refers to a structure which does not or cannot undergo metallothermic reduction and which used to hold the crystalline material in place, for example on a circuit board or other electronics device. Examples include metals, other crystalline materials, glasses, glass ceramics, ceramics, polymers, and adhesives.

“Doping,” as used herein, refers to the insertion into a crystalline composition of an element (referred to as a dopant) not normally found therein. Dopants often alter the electrical or optical properties of the composition. Examples include, but are not limited to, boron, arsenic, phosphorous, antimony, aluminum, gallium, cadmium germanium tellurium, or selenium.

“Chemically modifying,” as used herein, refers to the modification of the crystal composition or structure via a chemical reaction. Such reactions include, but are not limited to, acid-base, combustion, synthesis, photochemical, decomposition, ion exchange, or displacement reactions.

“Physically modifying,” as used herein, refers to the modification of the crystal composition or structure via a physical process, such as, but not limited to, crushing, grinding, cutting, pressure, heating, cooling, or ablation.

“Metallothermic,” as used herein, refers to a gas/solid displacement reaction wherein at least one solid oxide compound is at least partially converted to the base element or an alternative compound comprising the base element via chemical reaction. In some embodiments, the reaction is done in the gas phase with the gas comprising magnesium or calcium. However, in some cases, the metallothermic reduction is done via an electronically-mediated reaction.

“Powders,” as used herein, refers to finely dispersed solid particles with an average diameter along their shortest dimension of from about 10 nm to about 500 μm.

The current disclosure expands the scope of applications available for the manufacturing of unique structures, such as nanowires, films, and powders. Many powders and nanowires are made of oxide materials such silica, titania and alumina. Manufacturing of nanostructured materials, such as powders and nanowires may be accomplished by a variety of techniques that use either gas or solutions as its precursors. The use of typical semiconductor techniques such as deposition/growth, oxidation, photolithography, dry etching and wet etching, allow the manufacturing of some semiconductor nanowires and powders on substrates, such as silicon nanowires on top of a silicon wafer. However, all these methods have relative difficulty in producing large quantities of nanowires cheaply and none are capable of producing three dimensional structures comprising these substances.

Current embodiments disclose cheap, efficient and powerful ways to manufacture highly porous structures. The silicon zeolites and oxygen-extracted crystals made by the processes can be used in a wide range of applications such as; molecular sensing, catalysis, molecular sieves, opto-electronics, computing, energy storage, batteries, field electron transmitting (FET) and n-MOSFET or p-MOSFET, drug delivery, anti-microbial uses, cell culture, cell based assays, ion channel assays, organic hybrid polymer composites, inorganic hybrid polymer composites, health care, medicinally, cement, transparent electrical conductors, superconductors, super magnets, piezoelectric, pyroelectric, microwave-synthesis, anti-microbial, anti-cancer, petroleum production and refinement, quantum entanglement, metamaterials, energy, electronics, microelectronics, nanoelectronics, spintronics, chiral synthesis, gas sensing, gas separation, water purification, electrolysis, electrochemical reactions & synthesis, magnetic susceptibility, environmental gas clean up, carbon sequestration, catalytic converters, fiber optical devices, lenses, ion exchange, RFID, LEDs, OLEDs, refractory materials, conductors, computers, quantum computers, integrated circuits, quantum cascade lasers, extruded ceramic devices, missile covers, molecular separation, lighting, explosives, aerospace applications, heat sinks, thermoelectric sensors, thermocouples, pH meters, high temperature refractors, chemical lasers, as targets for mass spectrometry, UV-Vis optics, fluorescent dye cavities, nuclear reactions, transformers, solenoids, non-linear optics, electric motors, photovoltaics, metal removal, electrochemical reactions/synthesis, surfactants, adsorption, adhesives, phonon sensing, lighting, lasers biosensors, optical waveguides, photovoltaics, photo catalysis, electroluminescence and the like.

A first aspect comprises a process comprising the reaction of a general crystalline oxide substrate and metallothermic reduction via metallic gas, such as magnesium. However, as noted previously, the scope of the present disclosure extends beyond specific metallothermic reduction processes. More specifically, according to embodiments described herein, a crystalline structure may be fabricated by extracting oxygen from the oxygen-containing crystalline precursor.

The crystalline precursor may comprise any crystal structure (see, e.g., W. Borchardt-Ott, CRYSTALLOGRAPHY: AN INTRODUCTION (Springer 2011) herein incorporated by reference in its entirety). Embodiments include, but are not limited to, zeolites, mica, quartz, sapphire, oxyorthosilicate, perovskites, a nonlinear crystalline materials, metal oxide organic frameworks, metal organic frameworks, ALD crystals, sol gel crystals, a crystal made by sol-gel synthesis technique, quartz fibers, crystal fibers, ion exchanged crystals, zeolites, polyhedral oligomeric silsesquioxanes (POSS), POSS polymer films, zeolitic imidazolate frameworks (ZIFs), zeolite containing films and covalent organic frameworks (COFs) (see M. O'Keeffe and O. M. Yaghi, New Microporous Crystalline Materials: MOFS, COFS, and ZIFS, AMERICAN CRYSTALLOGRAPHIC ASS'N (2010), herein incorporated by reference in its entirety). One embodiment comprises zeolites, which, when subjected to the methods described herein, have unique properties that are advantageous. Another embodiment comprises sapphire. Another embodiment comprises quartz.

In some embodiments, the crystal may comprise defects, impurities, and/or twinning In some embodiments, the defects comprise point defects, substitution defects, Schottky defects, Frenkel defects, line defects, edge dislocations, screw dislocations, plane defects, small angle grain boundaries, stacking faults or twin boundaries.

Crystalline compositions may further be converted to powders subsequent to formation. The powders may comprise either porous or nonporous structures. The powders may have an average particle size of from about 0.01 μm to 500 μm. In some embodiments, the particles have an average particle size of about 0.01, 0.02, 0.03, 0.04, 0.05, 0.1, 0.2, 0.3, 0.4, 0.5, 0.6, 0.7, 0.8, 0.9, 1, 2, 3, 4, 5, 6, 7, 8, 9, 10, 15, 20, 25, 30, 40, 50, 60, 70, 80, 90, 100, 150, 200, 250, 300, 350, 400, 450, or 500 μm.

As noted above, oxygen is extracted from the crystalline precursor by reacting a metallic gas, such as magnesium, with the crystalline precursor in a heated inert atmosphere to form a metal-oxygen complex along a surface of the metal or metalloid oxide substrate. Examples of an inert atmosphere include nitrogen and argon. Also, in some embodiments, the atmosphere can be designed to favor reduction by having a partial pressure of hydrogen (e.g., 98% argon, 2% H₂). To facilitate the oxygen extraction, the inert atmosphere is heated to a reaction temperature, T, which, in the case of many crystalline precursors, will be between about 400° C. and about 900° C. For example, and not by way of limitation, for Linde Type 3 Zeolite, a suitable reaction temperature T will be approximately 660° C. and can be maintained for approximately two hours. In some embodiments, the reaction temperature is about 400° C., 425° C., 450° C., 475° C., 500° C., 525° C., 550° C., 575° C., 600° C., 625° C., 650° C., 675° C., 700° C., 725° C., 750° C., 775° C., 800° C., 825° C., 850° C., 875° C., or 900° C. In some embodiments, the reaction temperature is greater than 400° C., 425° C., 450° C., 475° C., 500° C., 525° C., 550° C., 575° C., 600° C., 625° C., 650° C., 675° C., 700° C., 725° C., 750° C., 775° C., 800° C., 825° C., 850° C., 875° C., or 900° C. In some cases, the crystalline precursor may be characterized by a thermal strain point and the inert atmosphere can be heated to a reaction temperature below the thermal strain point of the crystalline precursor. Reduced reaction temperatures are contemplated for low pressure reaction chambers.

In terms of energy needed for reduction of an oxide, it is possible to use Ellingham diagrams for the materials present in the precursor. Magnesium gas can reduce most of the common oxides (except for CaO, which can be etched later by other means) at reasonably lower temperatures than, for example, carbon gas. Therefore a zeolite made of a complex multi-component oxide can be extracted via metallothermic reduction using magnesium gas.

It is contemplated that a variety of suitable reduction gases can be utilized without departing from the scope of the present disclosure. For example, and not by way of limitation, it is contemplated that the metallic reducing gas may comprise magnesium, calcium, sodium, rubidium, or combinations thereof. In a simplified, somewhat ideal case, where the metallic gas comprises magnesium, the corresponding stoichiometric reaction with the silica glass substrate is as follows:

2Mg+SiO₂→Si+2MgO.

Analogous reactions would characteristic for similar reducing gases. Such reactions may be done on any unreactive or limitedly reactive surface, including metals, other crystals, glass, ceramic, glass-ceramic, fiber, optical fiber, fusion drawn glass, chemically strengthened glass or glass that is re-drawn and laminated with polymers.

In non-stoichiometric or more complex cases, reaction byproducts like Mg₂Si are generated and the reducing step described above can be followed by the byproduct removal steps described herein. To avoid byproduct generation and the need for the byproduct removal step, it is contemplated that the stoichiometry of the reduction can be tailored such that the metallic gas is provided in an amount that is not sufficient to generate the byproduct. However, in many cases, the composition of the crystalline precursor will be such that the generation of additional reaction byproducts is inevitable, in which case these additional byproducts can be removed by the etching and thermal byproduct removal steps described herein.

To enhance reduction, the crystalline precursor may be subjected to microwave or RF exposure while reacting the metallic gas with the metal or metalloid substrate. The metallic gas can be derived from any conventional or yet to be developed source including, for example, a metal source subject to microwave, plasma or laser sublimation, an electrical current, inductive heating, or a plasma arc to induce metal gas formation. In cases where the metallic gas is derived from a metal source, it is contemplated that the composition of the metal source can be varied while reacting the metallic gas with the metal or metalloid substrate to further enhance reduction.

Additional defects can be formed in the metal or metalloid substrate by irradiating the surface of the substrate with electrons. The resulting defects enable a more facile and extensive extraction of oxygen by the metallothermic reducing gas agent and, as such, can be used to enhance oxygen extraction by subjecting the glass substrate to electron beam irradiation prior to the above-described metallothermic reduction processes. Contemplated dosages include, but are not limited to, dosages from approximately 10 kGy to approximately 75 kGy (kGy is one thousand Gray units), with acceleration voltages of approximately 125 KV. Higher dosages and acceleration voltages are contemplated and deemed likely to be advantageous.

The metal-oxygen complex that is formed may be removed to yield a porous metal or metalloid structure. The end product may be a crystalline material comprising one or more types of atoms. For example, the product may comprise crystalline silicon, silicon carbide, silicon nitride, silicides, such as FeSi₂, silizanes, and silicates. The crystalline structure of the product may be the same or different than the starting material, and may be described by any crystal system, crystal family or lattice system. Further, the products may be found in ordered single or multilayer sheets. In some embodiments, the product will be in a crystalline powder form. In some embodiments, the products are crystalline in structure and have high porosities that may be a result of the metallothermic process or the porosity of the starting material, or both.

Although the various embodiments of the present disclosure are not limited to a particular removal process, it is noted that the metal-oxygen complex can be removed from the surface of the metal or metalloid substrate by executing a post-reaction acid etching step. For example, and not by way of limitation, post-reaction acid etching may be executed in a 1M HCl solution in water and alcohol (molar HCl (conc.): H₂O:EtOH (˜100%) ratio=0.66:4.72:8.88) for at least 2 hours. Alternate alcohols may also be used in the etching step. Depending on the porosity of the glass, some additional MgO may be trapped inside the glass and additional etching may be needed for longer periods of time with multiple flushes of the acidic mixture.

In some embodiments, the formed metal-oxygen complex is removed to yield a nanostructured essentially oxygen-free composition with a porosity of greater than 200 m²/g. In some embodiments, the formed material has a porosity from about 200 to about 1000, about 200 to about 900, about 200 to about 800, about 200 to about 700, about 200 to about 600, about 200 to about 500, about 200 to about 400, about 200 to about 300, about 300 to about 1000, about 300 to about 900, about 300 to about 800, about 300 to about 700, about 300 to about 600, about 300 to about 500, about 300 to about 400, about 400 to about 1000, about 400 to about 900, about 400 to about 800, about 400 to about 700, about 400 to about 600, about 400 to about 500, about 500 to about 1000, about 500 to about 800, about 500 to about 600, about 600 to about 1000, about 500 to about 800, or about 800 to about 1000 m²/g. In some embodiments, the formed material has a porosity of about 200, 225, 250, 275, 300, 350, 400, 450, 500, 550, 600, 650, 700, 750, 800, 900, or 1000 m²/g.

The metallothermically reduced crystals can be subsequently used for the further crystal growth of similar or different elements or compounds over them by processes such as epitaxial growth. Additionally, the substrates may be doped with other agents like metals either before or after metallothermic reduction. Alternatively, the crystalline surfaces may be patterned or masked during or before the oxygen extraction. For example, it has been found that masks made from graphite or vitreous carbon are effective.

### EXAMPLES

### Example 1

### Oxygen Extraction from Crystals

The zeolite used was a Linde-type class A zeolite (CAS 1318-02-1) made of 0.6 K₂O:4.0 Na₂O:1 Al₂O₃:2.0:0.1 SiO₂:x H₂O. The class A zeolites comprised a three-dimensional framework of tetrahedral coordinated T-atoms with cavities or channels, wherein the smallest opening is larger than six T-atoms. The possible T-atoms are silicon, Al, P, As, Ga, Ge, B, Be.

The magnesium source used was magnesium turnings (99.8% purity, Alfa Aesar) or magnesium powder (Sigma-Aldrich 254126-500G, reagent grade, 98%). The magnesium turnings or powder were put in a graphite or vitreous carbon crucible with the zeolite powder at a ratio of at least about 1:1, and covered with a graphite or EAGLE® glass lid.

The crucible was put into an oven under an argon atmosphere at a temperature between 600° C.-750° C. (e.g., 660° C.) for a period of 2 hours. After the reaction the original crystalline powder is transformed inside the crucible to a dark blackish brown powder. The reaction of the magnesium gas with the zeolite crystal lattice produced a monocrystalline state comprising single crystal silicon (silicon). The resulting product was darkly colored due to the MgO byproduct that stained the material. A second by-product of this reaction was the appearance of Mg₂Si which arises from a secondary reaction of the formed silicon with excess magnesium due to the non-balanced (excess) reaction.

### Example 2

### Completion of the MgO Formation

The residual unreacted magnesium turnings were removed from the crucible in Example 1, leaving behind the reacted crystalline powder. In order to remove any contaminating Mg₂Si formed in the reaction, and to help sublime away any excess magnesium, the converted powder was returned to the over under argon atmosphere and reacted for 8 hours at 660° C. After this step, essentially all of the powder was composed of MgO and oxygen-extracted crystalline material.

### Example 3

### Removal of MgO from the Crystal

Acid etching was done in 1M HCl solution (molar HCl:H₂O:EtOH ratio=0.66:4.72:8.88). Here, the powder and/or crystalline film was put into a Pyrex® container and etched for at least 2 hours with agitation to remove the MgO. The final result was a pure silicon zeolite or oxygen-free lattice. The etching process can be adjusted to control what materials are extracted. Ultrasonic exposure can be applied if needed. Also, multiple rounds of extraction may be required depending on how porous a particular crystal lattice is or its chemical composition. In the current case, a majority of the oxygen-containing lattice prior to metallothermic reduction was not silicon, but it was possible to remove all of these materials effectively. However, changing the base solvent solution may decrease or increase the acid-etched extractants. Such adjustments allow for changes in conductivity and porosity.

### Example 4

### Zeolite Product Analysis

Tables 1 through 5 show the progression of X-ray diffraction (“XRD”) data of the conversion process. Table 1 is the XRD of the starting material, an untreated Zeolite 3A:

| 2-Theta | d(Å) | Height | Height % | Phase ID | d(Å) | I % | h k l | 2-Theta | Delta |
|---|---|---|---|---|---|---|---|---|---|
| 7.213 | 12.2453 | 241 | 2.8 | Sodium | 12.2434 | 100 | 1 0 0 | 7.214 | 0.001 |
| 10.205 | 8.6614 | 247 | 2.9 | Sodium | 8.677 | 69 | 1 1 0 | 10.186 | −0.018 |
| 12.538 | 7.054 | 87 | 1 | Sodium | 7.083 | 35 | 1 1 1 | 12.487 | −0.052 |
| 16.131 | 5.49 | 154 | 1.8 | Sodium | 5.4891 | 25 | 2 1 0 | 16.134 | 0.003 |
| 21.809 | 4.072 | 151 | 1.8 | Sodium | 4.0914 | 36 | 3 0 0 | 21.704 | −0.105 |
| 24.143 | 3.6834 | 245 | 2.9 | Sodium | 3.6999 | 53 | 3 1 1 | 24.033 | −0.11 |
| 28.438 | 3.1361 | 8514 | 100 | Silicon | 3.137 | 100 | 1 1 1 | 28.429 | −0.009 |
| 30.065 | 2.9699 | 156 | 1.8 | Sodium | 2.9757 | 55 | 4 1 0 | 30.005 | −0.06 |
| 31.431 | 2.8438 | 104 | 1.2 | | | | | | |
| 36.935 | 2.4317 | 282 | 3.3 | MgO | 2.4306 | 12.5 | 1 1 1 | 36.953 | 0.018 |
| 38.454 | 2.3391 | 2468 | 29 | Al | 2.3412 | 100 | 1 1 1 | 38.419 | −0.035 |
| 42.985 | 2.1025 | 2030 | 23.8 | Sodium | 2.105 | 3 | 5 3 0 | 42.931 | −0.054 |
| 44.679 | 2.0266 | 953 | 11.2 | Al | 2.0275 | 45.5 | 2 0 0 | 44.658 | −0.021 |
| 47.296 | 1.9204 | 3479 | 40.9 | Silicon | 1.921 | 55.5 | 2 2 0 | 47.279 | −0.017 |
| 56.122 | 1.6375 | 1604 | 18.8 | Silicon | 1.6382 | 30 | 3 1 1 | 56.094 | −0.028 |
| 62.393 | 1.4871 | 621 | 7.3 | MgO | 1.4888 | 48.1 | 2 2 0 | 62.316 | −0.078 |
| 65.074 | 1.4322 | 390 | 4.6 | Al | 1.4337 | 23.1 | 2 2 0 | 64.999 | −0.076 |
| 69.089 | 1.3584 | 257 | 3 | Silicon | 1.3584 | 6.8 | 4 0 0 | 69.093 | 0.004 |
| 76.332 | 1.2466 | 348 | 4.1 | Silicon | 1.2465 | 9.4 | 3 3 1 | 76.334 | 0.002 |
| 78.148 | 1.2221 | 224 | 2.6 | Potassium | 1.2218 | 2.4 | 9 4 2 | 78.168 | 0.02 |

The automated software identified the two basic chemical mixtures in the zeolite crystal as noted in Table 1.

Table 2 shows the XRD spectrum for metallothermically reduced Zeolite 3A powder without exposure to a hydrochloric acid etch:

| 2-Theta | d(Å) | Height | Height % | Phase ID | d(Å) | I % | h k l | 2-Theta | Delta |
|---|---|---|---|---|---|---|---|---|---|
| 7.209 | 12.2495 | 31251 | 71.7% | Sodium | 8.6760 | 100.0% | 1 0 0 | 7.211 | 0.002 |
| 10.188 | 8.6813 | 43586 | 100.0% | Sodium | 7.0880 | 69.0% | 1 1 0 | 10.181 | −0.007 |
| 12.478 | 7.0892 | 18916 | 43.4% | Potassium | 6.1430 | 21.7% | 1 1 1 | 12.476 | −0.002 |
| 13.920 | 6.3569 | 174 | 0.4% | | 5.4900 | | | | |
| 14.408 | 6.1394 | 523 | 1.2% | Potassium | 5.0120 | 5.6% | 2 0 0 | 14.416 | 0.008 |
| 16.130 | 5.4913 | 14078 | 32.3% | Potassium | 4.3410 | 3.8% | 2 1 0 | 16.128 | −0.002 |
| 17.683 | 5.0128 | 218 | 0.5% | Potassium | 4.0930 | 4.6% | 2 1 1 | 17.679 | −0.004 |
| 20.442 | 4.3412 | 3051 | 7.0% | Potassium | 3.8826 | 0.5% | 2 2 0 | 20.441 | −0.001 |
| 21.384 | 4.1519 | 1526 | 3.5% | | 3.7025 | | | | |
| 21.696 | 4.0930 | 16955 | 38.9% | Potassium | 3.4053 | 9.2% | 3 0 0 | 21.696 | 0.000 |
| 22.887 | 3.8829 | 523 | 1.2% | Potassium | 3.2833 | 0.8% | 3 1 0 | 22.885 | −0.002 |
| 24.016 | 3.7022 | 26718 | 61.3% | Potassium | 3.0699 | 20.8% | 3 1 1 | 24.018 | 0.002 |
| 25.113 | 3.5446 | 174 | 0.4% | Potassium | 2.9788 | 0.9% | 2 2 2 | 25.102 | −0.011 |
| 26.147 | 3.4055 | 5274 | 12.1% | Potassium | 2.8946 | 9.8% | 3 2 0 | 26.145 | −0.002 |
| 27.137 | 3.2821 | 22403 | 51.4% | Sodium | 2.7465 | 47.0% | 3 2 1 | 27.147 | 0.010 |
| 29.064 | 3.0697 | 349 | 0.8% | Potassium | 2.6191 | 4.2% | 4 0 0 | 29.066 | 0.002 |
| 29.973 | 2.9781 | 21967 | 50.4% | Potassium | 2.5079 | 30.6% | 4 1 0 | 29.980 | 0.007 |
| 30.867 | 2.8944 | 3138 | 7.2% | Sodium | 2.3641 | 9.0% | 3 3 0 | 30.869 | 0.002 |
| 32.576 | 2.7456 | 4184 | 9.6% | Potassium | 2.2426 | 28.1% | 4 2 0 | 32.586 | 0.010 |
| 33.406 | 2.6795 | 1351 | 3.1% | Potassium | 2.1720 | 6.0% | 4 2 1 | 33.414 | 0.008 |
| 34.207 | 2.6179 | 13337 | 30.6% | Potassium | 2.1068 | 4.9% | 3 3 2 | 34.224 | 0.017 |
| 35.775 | 2.5067 | 1961 | 4.5% | Sodium | 2.0471 | 5.0% | 4 2 2 | 35.792 | 0.017 |
| 36.542 | 2.4559 | 1787 | 4.1% | Sodium | 12.2500 | 4.0% | 4 3 0 | 36.559 | 0.017 |
| 37.295 | 2.4081 | 131 | 0.3% | Potassium | 1.9186 | 0.7% | 5 1 0 | 37.312 | 0.017 |
| 38.032 | 2.3632 | 915 | 2.1% | Sodium | 1.8315 | 3.0% | 5 1 1 | 38.047 | 0.015 |
| 39.474 | 2.2815 | 436 | 1.0% | Sodium | 1.7373 | 1.0% | 5 2 0 | 39.466 | −0.008 |
| 40.179 | 2.2418 | 872 | 2.0% | Potassium | 1.6879 | 0.8% | 5 2 1 | 40.194 | 0.015 |
| 41.544 | 2.1706 | 2441 | 5.6% | Potassium | 1.6425 | 14.4% | 4 4 0 | 41.571 | 0.027 |
| 42.232 | 2.1375 | 1613 | 3.7% | Potassium | 1.5994 | 0.1% | 4 4 1 | 42.246 | 0.014 |
| 42.891 | 2.1060 | 1177 | 2.7% | Sodium | 1.5238 | 3.0% | 5 3 0 | 42.908 | 0.017 |
| 43.549 | 2.0761 | 1002 | 2.3% | Sodium | 1.4791 | 4.0% | 5 3 1 | 43.557 | 0.008 |
| 44.207 | 2.0465 | 2964 | 6.8% | Potassium | 1.4276 | 1.3% | 6 0 0 | 44.222 | 0.015 |
| 44.851 | 2.0186 | 218 | 0.5% | Potassium | 1.3999 | 0.4% | 6 1 0 | 44.865 | 0.014 |
| 47.343 | 1.9177 | 1961 | 4.5% | Sodium | 1.3568 | 7.0% | 5 4 0 | 47.367 | 0.024 |
| 47.955 | 1.8947 | 1482 | 3.4% | Sodium | 1.3247 | 4.0% | 5 4 1 | 47.976 | 0.021 |
| 49.192 | 1.8511 | 349 | 0.8% | Potassium | 1.2949 | 2.5% | 6 2 2 | 49.180 | −0.012 |
| 49.743 | 1.8309 | 959 | 2.2% | Sodium | 1.2462 | 3.0% | 6 3 0 | 49.759 | 0.016 |
| 52.063 | 1.7541 | 349 | 0.8% | Potassium | 1.2223 | 0.6% | 7 0 0 | 52.097 | 0.034 |
| 52.642 | 1.7373 | 3400 | 7.8% | Sodium | | 13.0% | 5 5 0 | 52.642 | 0.000 |
| 53.221 | 1.7194 | 479 | 1.1% | Potassium | | 1.6% | 7 1 1 | 53.232 | 0.011 |
| 53.770 | 1.7028 | 87 | 0.2% | Potassium | | 1.3% | 6 4 0 | 53.792 | 0.022 |
| 54.305 | 1.6866 | 1743 | 4.0% | Potassium | | 2.3% | 7 2 0 | 54.349 | 0.044 |
| 54.869 | 1.6709 | 349 | 0.8% | Potassium | | 1.1% | 7 2 1 | 54.902 | 0.033 |
| 55.936 | 1.6408 | 131 | 0.3% | Potassium | | 0.6% | 6 4 2 | 55.998 | 0.062 |
| 56.514 | 1.6266 | 785 | 1.8% | Sodium | | 4.0% | 7 2 2 | 56.530 | 0.016 |
| 57.079 | 1.6123 | 131 | 0.3% | Potassium | | 0.1% | 7 3 0 | 57.079 | 0.000 |
| 57.581 | 1.5987 | 1351 | 3.1% | Sodium | | 6.0% | 7 3 1 | 57.609 | 0.028 |
| 58.647 | 1.5721 | 1090 | 2.5% | Potassium | | 3.7% | 6 5 0 | 58.677 | 0.030 |
| 60.214 | 1.5349 | 218 | 0.5% | Potassium | | 2.0% | 8 0 0 | 60.247 | 0.033 |
| 60.732 | 1.5230 | 392 | 0.9% | Potassium | | 0.1% | 8 1 0 | 60.766 | 0.034 |
| 61.280 | 1.5114 | 174 | 0.4% | Potassium | | 1.0% | 7 4 1 | 61.280 | 0.000 |
| 62.283 | 1.4890 | 174 | 0.4% | Potassium | | 5.3% | 8 2 0 | 62.304 | 0.021 |
| 62.770 | 1.4782 | 567 | 1.3% | Potassium | | 0.8% | 8 2 1 | 62.812 | 0.042 |
| 63.318 | 1.4676 | 305 | 0.7% | Potassium | | 0.6% | 6 5 3 | 63.319 | 0.001 |
| 64.306 | 1.4471 | 262 | 0.6% | Potassium | | 1.3% | 6 6 0 | 64.323 | 0.017 |
| 64.792 | 1.4371 | 131 | 0.3% | Potassium | | 0.5% | 6 6 1 | 64.823 | 0.031 |
| 65.309 | 1.4274 | 610 | 1.4% | Potassium | | 0.7% | 7 4 3 | 65.320 | 0.011 |
| 65.780 | 1.4178 | 392 | 0.9% | Potassium | | 0.2% | 5 5 5 | 65.816 | 0.036 |
| 66.768 | 1.3994 | 1046 | 2.4% | Sodium | | 5.0% | 8 3 2 | 66.797 | 0.029 |
| 68.742 | 1.3645 | 436 | 1.0% | Sodium | | 2.0% | 9 0 0 | 68.739 | −0.003 |
| 69.182 | 1.3560 | 1613 | 3.7% | Potassium | | 2.8% | 8 3 3 | 69.232 | 0.050 |
| 70.701 | 1.3318 | 174 | 0.4% | Potassium | | 0.1% | 9 2 0 | 70.672 | −0.029 |
| 71.110 | 1.3241 | 479 | 1.1% | Potassium | | 0.8% | 6 5 5 | 71.150 | 0.040 |
| 72.521 | 1.3016 | 305 | 0.7% | Potassium | | 0.3% | 7 6 2 | 72.574 | 0.053 |
| 73.007 | 1.2943 | 697 | 1.6% | Potassium | | 2.3% | 9 3 0 | 73.046 | 0.039 |
| 75.813 | 1.2532 | 218 | 0.5% | Potassium | | 2.7% | 8 4 4 | 75.854 | 0.041 |
| 76.360 | 1.2467 | 218 | 0.5% | Potassium | | 2.5% | 9 4 0 | 76.318 | −0.042 |

Table 3 shows the XRD data for metallothermically reduced Zeolite 3A powder with a single etch in 1M hydrochloric acid:

| 2-Theta | d(Å) | Height | Height % | Phase ID | d(Å) | I % | h k l | 2-Theta | Delta |
|---|---|---|---|---|---|---|---|---|---|
| 7.179 | 12.2789 | 19484 | 100.0% | Potassium | 8.6880 | 100.0% | 1 0 0 | 7.193 | 0.014 |
| 10.174 | 8.6825 | 12041 | 61.8% | Potassium | 7.0880 | 29.7% | 1 1 0 | 10.180 | 0.006 |
| 12.478 | 7.0892 | 7560 | 38.8% | Potassium | 5.4850 | 21.7% | 1 1 1 | 12.476 | −0.002 |
| 16.146 | 5.4913 | 5709 | 29.3% | Potassium | 4.9990 | 3.8% | 2 1 0 | 16.127 | −0.019 |
| 17.730 | 5.0128 | 585 | 3.0% | Potassium | 4.3410 | 4.6% | 2 1 1 | 17.679 | −0.051 |
| 20.441 | 4.3412 | 682 | 3.5% | Potassium | 4.0900 | 0.5% | 2 2 0 | 20.441 | 0.000 |
| 21.712 | 4.0930 | 2767 | 14.2% | Potassium | 3.7000 | 9.2% | 3 0 0 | 21.695 | −0.017 |
| 24.032 | 3.7018 | 3760 | 19.3% | Sodium | 3.5390 | 53.0% | 3 1 1 | 24.020 | −0.012 |
| 25.143 | 3.5446 | 117 | 0.6% | Potassium | 3.2779 | 0.9% | 2 2 2 | 25.102 | −0.041 |
| 26.147 | 3.4055 | 214 | 1.1% | Potassium | 3.1379 | 9.8% | 3 2 0 | 26.145 | −0.002 |
| 27.183 | 3.2817 | 2241 | 11.5% | Potassium | 2.9742 | 10.3% | 3 2 1 | 27.151 | −0.032 |
| 28.422 | 3.1360 | 2728 | 14.0% | Silicon | 2.7453 | 100.0% | 1 1 1 | 28.439 | 0.017 |
| 30.021 | 2.9772 | 2280 | 11.7% | Sodium | 2.6134 | 55.0% | 4 1 0 | 29.990 | −0.031 |
| 30.851 | 2.8944 | 292 | 1.5% | Sodium | 2.4368 | 9.0% | 3 3 0 | 30.868 | 0.017 |
| 32.591 | 2.7449 | 390 | 2.0% | Sodium | 2.3474 | 12.0% | 4 2 0 | 32.595 | 0.004 |
| 33.530 | 2.6791 | 175 | 0.9% | Sodium | 2.2493 | 4.0% | 4 2 1 | 33.419 | −0.111 |
| 34.285 | 2.6173 | 1754 | 9.0% | Sodium | 2.1039 | 22.0% | 3 3 2 | 34.232 | −0.053 |
| 35.884 | 2.5064 | 136 | 0.7% | Potassium | 2.0361 | 7.9% | 4 2 2 | 35.797 | −0.087 |
| 36.856 | 2.4308 | 682 | 3.5% | Periclase | 12.3000 | 11.5% | 1 1 1 | 36.950 | 0.094 |
| 38.314 | 2.3631 | 1091 | 5.6% | Potassium | 1.9209 | 3.3% | 5 1 1 | 38.049 | −0.265 |
| 40.053 | 2.2418 | 253 | 1.3% | Potassium | 1.7329 | 0.8% | 5 2 1 | 40.193 | 0.140 |
| 42.954 | 2.1051 | 6488 | 33.3% | Periclase | 1.6830 | 100.0% | 2 0 0 | 42.928 | −0.026 |
| 44.459 | 2.0462 | 935 | 4.8% | Sodium | 1.6387 | 9.0% | 6 0 0 | 44.227 | −0.232 |
| 47.281 | 1.9204 | 1344 | 6.9% | Silicon | 1.5935 | 54.9% | 2 2 0 | 47.295 | 0.014 |
| 52.783 | 1.7365 | 546 | 2.8% | Potassium | 1.4878 | 6.5% | 5 5 0 | 52.666 | −0.117 |
| 54.476 | 1.6864 | 136 | 0.7% | Sodium | 1.4350 | 6.0% | 7 2 0 | 54.356 | −0.120 |
| 56.075 | 1.6377 | 623 | 3.2% | Silicon | 1.3941 | 29.7% | 3 1 1 | 56.113 | 0.038 |
| 57.817 | 1.5986 | 136 | 0.7% | Potassium | 1.3560 | 2.0% | 7 3 1 | 57.615 | −0.202 |
| 58.883 | 1.5680 | 136 | 0.7% | Silicon | 1.2706 | 0.1% | 2 2 2 | 58.847 | −0.036 |
| 62.362 | 1.4885 | 2280 | 11.7% | Periclase | 1.2459 | 48.7% | 2 2 0 | 62.327 | −0.035 |
| 64.933 | 1.4371 | 156 | 0.8% | Potassium | 1.2149 | 0.5% | 6 6 1 | 64.823 | −0.110 |
| 67.083 | 1.3903 | 175 | 0.9% | Potassium | | 0.1% | 7 5 2 | 67.290 | 0.207 |
| 69.228 | 1.3560 | 253 | 1.3% | Potassium | | 2.8% | 8 3 3 | 69.232 | 0.004 |
| 74.638 | 1.2694 | 156 | 0.8% | Periclase | | 5.8% | 3 1 1 | 74.717 | 0.079 |
| 76.377 | 1.2461 | 156 | 0.8% | Silicon | | 9.5% | 3 3 1 | 76.363 | −0.014 |

Table 4 shows the XRD data for metallothermically reduced Zeolite 3A powder with two etching rounds in 1M hydrochloric acid:

| 2-Theta | d(Å) | Height | Height % | Phase ID | d(Å) | I % | h k l | 2-Theta | Delta |
|---|---|---|---|---|---|---|---|---|---|
| 18.983 | 4.6712 | 106 | 0.6 | Spinel | 4.66 | 35 | 1 1 1 | 19.029 | 0.046 |
| 24.08 | 3.6928 | 95 | 0.5 | Magnesium | 3.69 | 100 | | 24.098 | 0.019 |
| 28.406 | 3.1395 | 17806 | 100 | Silicon | 3.137 | 100 | 1 1 1 | 28.429 | 0.023 |
| 31.37 | 2.8493 | 230 | 1.3 | Spinel | 2.858 | 40 | 2 2 0 | 31.272 | −0.098 |
| 36.839 | 2.4378 | 233 | 1.3 | Spinel | 2.437 | 100 | 3 1 1 | 36.852 | 0.013 |
| 44.286 | 2.0437 | 96 | 0.5 | | | | | | |
| 44.817 | 2.0207 | 160 | 0.9 | Spinel | 2.02 | 65 | 4 0 0 | 44.833 | 0.015 |
| 47.28 | 1.921 | 7901 | 44.4 | Silicon | 1.921 | 55.5 | 2 2 0 | 47.279 | −0.001 |
| 56.091 | 1.6383 | 3784 | 21.2 | Silicon | 1.6382 | 30 | 3 1 1 | 56.094 | 0.003 |
| 59.306 | 1.557 | 66 | 0.4 | Spinel | 1.5554 | 45 | 5 1 1 | 59.371 | 0.065 |
| 65.153 | 1.4306 | 105 | 0.6 | Spinel | 1.4289 | 55 | 4 4 0 | 65.242 | 0.09 |
| 69.088 | 1.3585 | 623 | 3.5 | Silicon | 1.3584 | 6.8 | 4 0 0 | 69.093 | 0.006 |
| 76.33 | 1.2466 | 778 | 4.4 | Silicon | 1.2465 | 9.4 | 3 3 1 | 76.334 | 0.004 |

Finally, Table 5 shows the XRD data for metallothermically reduced Zeolite 3A powder with three etching rounds in 1M hydrochloric acid.

| 2-Theta | d(Å) | Height | Height % | Phase ID | d(Å) | I % | h k l | 2-Theta | Delta |
|---|---|---|---|---|---|---|---|---|---|
| 28.452 | 3.1345 | 16320 | 100 | Silicon | 3.1357 | 100 | 1 1 1 | 28.441 | −0.011 |
| 31.107 | 2.8728 | 76 | 0.5 | Spinel | 2.858 | 40 | 2 2 0 | 31.272 | 0.165 |
| 31.477 | 2.8398 | 90 | 0.6 | | | | | | |
| 36.872 | 2.4357 | 170 | 1 | Spinel | 2.437 | 100 | 3 1 1 | 36.852 | −0.02 |
| 44.881 | 2.0179 | 157 | 1 | Spinel | 2.02 | 65 | 4 0 0 | 44.833 | −0.048 |
| 47.297 | 1.9203 | 7309 | 44.8 | Silicon | 1.9202 | 54.9 | 2 2 0 | 47.3 | 0.003 |
| 56.122 | 1.6375 | 3670 | 22.5 | Silicon | 1.6376 | 29.7 | 3 1 1 | 56.12 | −0.003 |
| 59.274 | 1.5577 | 53 | 0.3 | Spinel | 1.5554 | 45 | 5 1 1 | 59.371 | 0.097 |
| 65.278 | 1.4282 | 104 | 0.6 | Spinel | 1.4289 | 55 | 4 4 0 | 65.242 | −0.035 |
| 69.133 | 1.3577 | 589 | 3.6 | Silicon | 1.3578 | 6.9 | 4 0 0 | 69.126 | −0.007 |
| 76.376 | 1.2459 | 752 | 4.6 | Silicon | 1.246 | 9.5 | 3 3 1 | 76.372 | −0.004 |

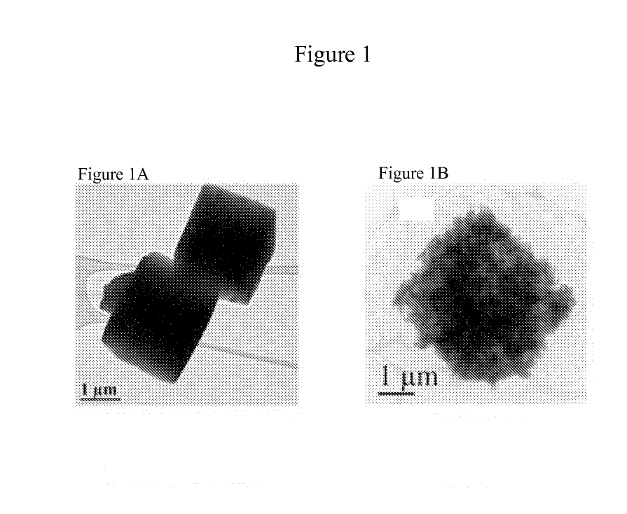

After 3 rounds of acid etching a material that is extremely pure in just silicon was recovered (Table 5). After metallothermic reduction, the resulting cube size was fairly equivalent to the initial zeolite dimensions of 3 by 3 by 4 microns (see FIG. 1B).

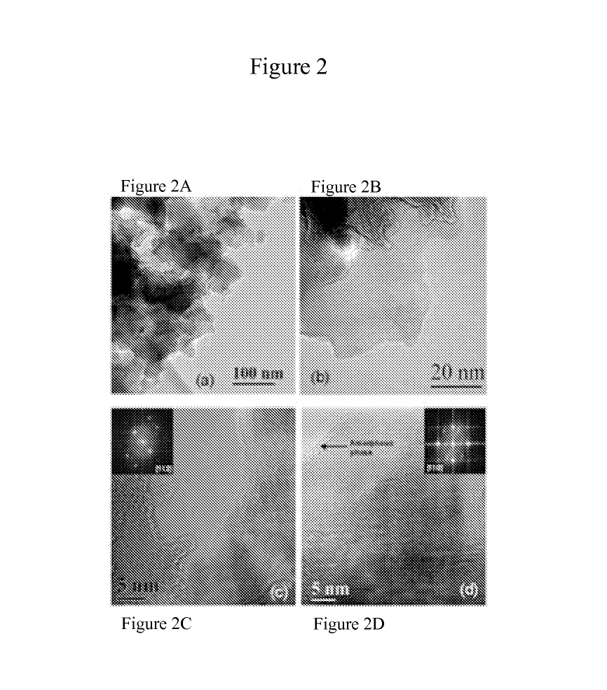

FIGS. 2A and 2B show low magnification TEM bright field (“BF”) images of a commercial zeolite after metallothermic reduction and acid etching. Two different types of primary structures are visible. The first structure comprises an interconnected pattern with pores of diameter varying between 30-60 nm within them (FIG. 2A). The other structure is a more lamellar structure, as shown in FIG. 2B. High resolution TEM on similar structures are shown in FIGS. 2C and 2D, respectively, along with the fast fourier transform (“FFT”) of their lattice fringes. Calculation of the lattice fringes showed a significant reduction in d-spacing (5.49 Å) with a space group of Fd-3m. This corresponds well with crystalline silicon that has a diamond cubic structure. Some amorphous phase is also observed surrounding the crystalline silicon lamella. Unlike the commercial zeolite, this material is very stable under the electron beam, indicating that the material is a semiconductor similar to crystalline silicon.

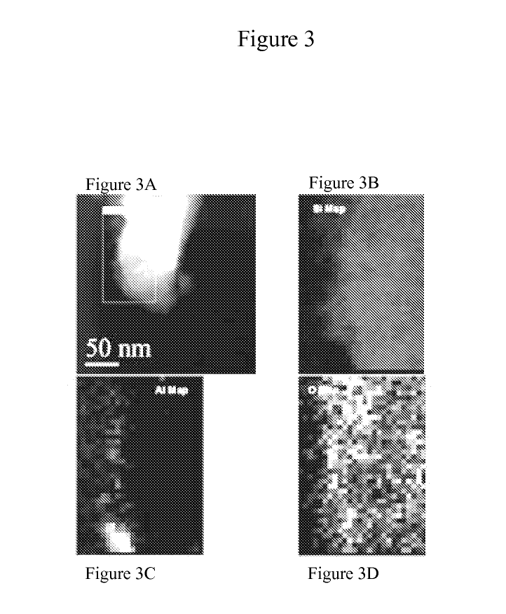

FIG. 3 shows the electron energy loss spectroscopy (“EELS”) mapping of a “flaky” region. The maps reveal that the flakes are indeed silicon and the outer amorphous regions are mostly aluminum oxide. Very small amount of oxygen may be present in the bulk of the material.

### Example 5

### Additional Etching Procedures

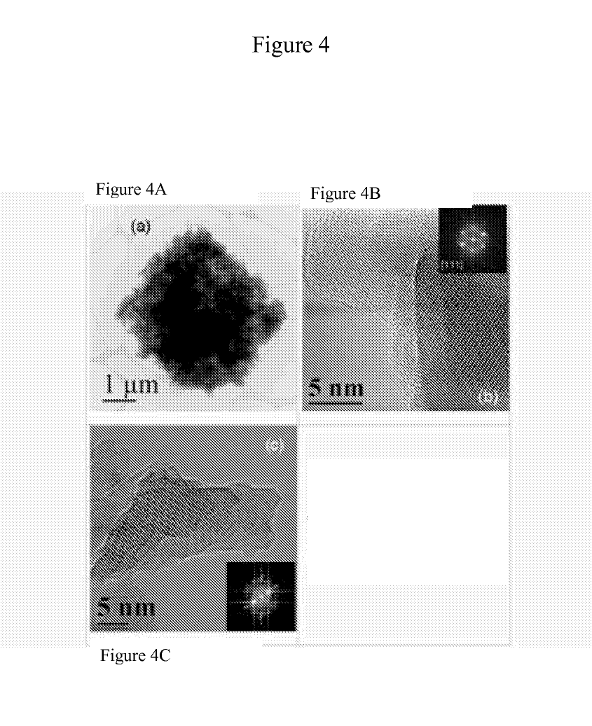

To reduce the residual amorphous components from the surrounding silicon particles, the powder was acid etched for second time. FIG. 4A shows a low magnification image of the material. The shape of this particle corresponds to the original cubic structure, only flatter. A closer look at the particles reveals that they are made of thin sheet-like structures as shown in FIGS. 4B and 4C. From the FFT of the lattice fringes (inset) it is clear that these flakes are thin sheets of silicon. Moreover the amorphous layer visible previously is almost gone, leaving a layer less than 1 nm thick. The image indicates that the metallothermic reduction process has kept the overall structure with the silicon intact and the process only removed the oxygen and other elements, like aluminum, potassium, magnesium and sodium.

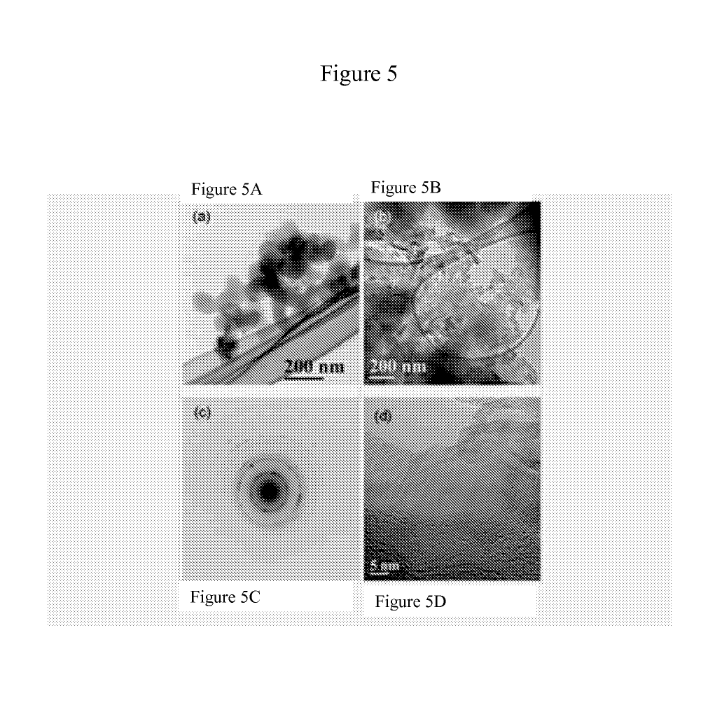

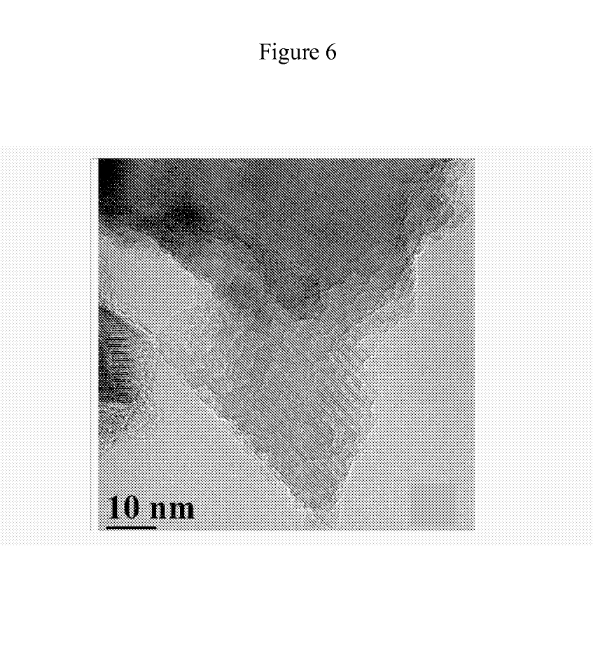

To exfoliate the flakes, the etched sample was sonicated in NMP and centrifuged at 14000 RPM after a pre-cut centrifugation of 7,500 RPM. The “pre-cut” pull down is done to remove the heavier particles post sonication. Low magnification TEM images showed different carbonaceous materials as shown in FIG. 5A. FIG. 5B shows another low magnification image of the same sample but different region. The TEM reveals some paper like sheets clustered together along with some elongated crystalline structures. The area selected to obtain a SAED pattern of the region is shown in FIG. 5C. The ring pattern with some spots in the SAED indicates that the region is polycrystalline in nature with some orientation. Calculations of the ring diffraction pattern resemble more of a cubic silicon with Fad-3m structure rather than hexagonal graphite like with P63/mM space group. FIG. 5D shows a high resolution TEM image of a flat region. The image reveals the presence of a layered structure similar to that seen in graphite particles. FIG. 6 shows a high resolution TEM image of the crystalline region at the edges of the cluster. From the lattice fringes it is clear that these particles are similar to the silicon particles that were observed before. From the structure it seems to have retained a flakey terraced nature and is not exfoliated. This means that the final structure of these methallothermal-reduced silicon layers depends heavily on the starting structure of the zeolite particles and may be well anchored in place by inter-lattice bonds or through framework silicon “connector” bonds.

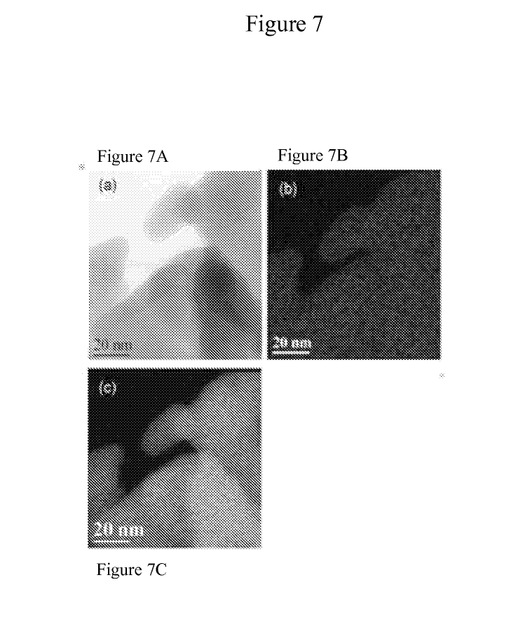

Energy filtered TEM (“EFTEM”) was performed on a flat region to look for the presence of silicon or graphite. FIGS. 7A-C shows the BFTEM zero loss image, silicon map, and carbon map respectively. Since carbon and silicon are present throughout the sample, it could be that the silicon films have absorbed the N-methyl-2-pyrrolidone solvent during exfoliation. It is believed that the carbon observed in the lattice is equivalent to 1-methyl-2-pyrrolidone being trapped inside the cage lattice since no sign of carbon was observed prior to exfoliation and that the carbon image tracks exactly with the silicon image.

### Prospective Application of New Materials

Note that the conductivity of the modified zeolite cube in FIG. 1B may be used as a sensing transistor wherein the electrical current through the framework can now be affected by impedance changes within the cage-like structure upon interaction with the cage. Current flow across this type of cage-like transistor/sensor should provide a new form of “sensistor.” Green et al. have published a paper describing a semiconductor zeolite as proof of concept. However, in Green et al. the process used a CdS doping wherein no oxygen extraction was done to the zeolite lattice (see Green et al., 89 Photocatalytic Oxidation of Propane-2-01 by Semiconductor-Zeolite Composites, J. CHEM. SOC. FARADAY TRANS. 1867-1870 (1993), herein incorporated by reference).

We claim:

1. A method of forming an essentially oxygen free crystalline composition comprising:
a. subjecting an oxygen-containing crystalline precursor to a metallothermic process; and
b. removing reaction by-products to give an essentially oxygen-free crystalline composition.

2. The method of claim 1, wherein the oxygen-containing crystalline precursor of the essentially oxygen-free crystalline composition comprises two or more elements other than oxygen.

3. The method of claim 1, wherein the oxygen-containing crystalline precursor comprises a zeolite, mica, quartz, sapphire, oxyorthosilicate, perovskite, a nonlinear crystalline material, metal oxide organic framework, metal organic framework, ALD crystal, sol gel crystal, quartz fiber, crystal fiber, ion exchanged crystal, polyhedral oligomeric silsesquioxane (POSS), POSS polymer film, zeolitic imidazolate framework (ZIFs), zeolite-containing film, or covalent organic framework (COFs).

4. The method of claim 3, wherein the oxygen-containing crystalline precursor comprises a zeolite, mica, quartz, sapphire, oxyorthosilicate, or perovskite.

5. The method of claim 1, wherein the essentially oxygen-free crystalline composition comprises a periodic arrangement of holes.

6. The method of claim 1, wherein the essentially oxygen-free crystalline composition comprises a porosity of greater than 200 m²/gram.

7. The method of claim 1, wherein the subjecting the oxygen-containing crystalline precursor to a metallothermic process comprises heating to a temperature of greater than 400° C. for more than 2 hours.

8. The method of claim 1, wherein the removing reaction by-products comprises acid etching the essentially oxygen-free crystalline composition.

9. The method of claim 1, further comprising modifying the oxygen-containing crystalline precursor.

10. The method of claim 9, wherein modifying comprises doping, chemically modifying, or physically modifying the oxygen-containing crystalline precursor.

11. The method of claim 1, further comprising modifying the essentially oxygen-free crystalline composition.

12. The method of claim 11, wherein modifying the essentially oxygen-free crystalline composition comprises doping, chemically modifying, or physically modifying the essentially oxygen-free crystalline composition.

13. The method of claim 1, further comprising masking or patterning the oxygen-containing crystalline precursor or the essentially oxygen-free crystalline composition.

14. The method of claim 1, further comprising use of the essentially oxygen-free crystalline composition growing crystals.

15. The method of claim 14, wherein growing crystals comprises epitaxy.
